(19) United States
(12) Patent Application Publication
(10) Pub. No.: US 2026/0142642 A1
(43) Pub. Date: May 21, 2026

(54) BULK ACOUSTIC WAVE (BAW) RESONATOR INCLUDING BILATERAL DIELECTRIC LAYERS FOR IMPROVED QUALITY FACTOR AND METHOD OF MAKING

(71) Applicant: RF360 Singapore Pte. Ltd., Singapore (SG)

(72) Inventors: Robert Brem, Buchloe (DE); Marc Esquius Morote, Munich (DE)

(21) Appl. No.: 18/950,666

(22) Filed: Nov. 18, 2024

(51) Int. Cl. H03H 9/13; H03H 3/02; H03H 9/17

(52) U.S. Cl. CPC H03H 9/131; H03H 3/02; H03H 9/173; H03H 9/175; H03H 2003/021; H03H 2003/025

(57) ABSTRACT

As the frequencies of microacoustic filter applications increase to address the needs of future technologies, the quality factor Q, which is a measure of energy efficiency, decreases, and the performance of microacoustic filters based on BAW resonators correspondingly decreases. In an exemplary BAW resonator, dielectric layers are disposed on each side of a piezoelectric layer and between the top and bottom electrode layers, which may be formed of metal, to reduce the acoustic/viscous losses that occur in the electrode layers. Inclusion of the bilateral dielectric layers between the top and bottom electrode layers shifts more energy to non-metallic layers to reduce acoustic energy losses. In some examples, a thickness of each of the dielectric layers may be up to thirty percent of a distance between the top and bottom electrode layers.

### TECHNICAL FIELD

The technology of the disclosure relates generally to wireless transceivers and other components that employ acoustic filters and, more specifically, to microacoustic filters employing bulk acoustic wave (BAW) resonators.

### BACKGROUND

Electronic devices may use radio-frequency (RF) signals to communicate information that enables voice communication, uploading and downloading of media (e.g., audio and video), remote control of household devices, and reception of global positioning information, for example. To transmit or receive the radio-frequency signals within a given frequency band allocated for such communications, the electronic device may use filters that pass signals within the frequency band and suppress (e.g., attenuate) jammers or noise at frequencies outside of the frequency band. It can be challenging, however, to design and manufacture a filter that provides filtering for radio-frequency applications, especially those that operate at frequencies above five (5) gigahertz (GHz).

### SUMMARY

Aspects disclosed in the detailed description include bulk acoustic wave (BAW) resonators, including bilateral dielectric layers for improved quality factor (Q). Methods of making the BAW resonator, including bilateral dielectric layers, are also disclosed. As the frequencies of microacoustic filter applications increase to address the needs of future technologies, the quality factor Q, which is a measure of energy efficiency, decreases, and the performance of microacoustic filters based on BAW resonators correspondingly decreases. In an exemplary BAW resonator, dielectric layers are disposed on each side of a piezoelectric layer and between the top and bottom electrode layer, which may be formed of metal, to reduce the acoustic/viscous losses that occur in the electrode layers. Inclusion of the bilateral dielectric layers between the top and bottom electrode layers shifts more energy to non-metallic layers to reduce acoustic energy losses. In some examples, a thickness of each of the dielectric layers may be up to thirty percent of a distance between the top and bottom electrode layers.

In this regard, in one aspect, a BAW resonator is disclosed. The BAW resonator includes a piezoelectric layer, a first electrode layer on a first side of the piezoelectric layer, a second electrode layer on a second side of the piezoelectric layer, a first dielectric layer between the first electrode layer and the first side of the piezoelectric layer, and a second dielectric layer between the second electrode layer and the second side of the piezoelectric layer.

In another aspect, a method of manufacturing a BAW resonator is disclosed. The method includes forming a piezoelectric layer, forming a first electrode layer on a first side of the piezoelectric layer, forming a second electrode layer on a second side of the piezoelectric layer, forming a first dielectric layer between the first electrode layer and the first side of the piezoelectric layer, and forming a second dielectric layer between the second electrode layer and the second side of the piezoelectric layer.

### BRIEF DESCRIPTION OF THE DRAWINGS

FIG. 1 illustrates an example operating environment for operating a bulk acoustic wave (BAW) resonator with bilateral dielectric layers between the top and bottom electrode layers to reduce energy losses in the metal layers of the electrode layers;

FIG. 2 illustrates an example wireless transceiver including at least one microacoustic filter, including a BAW resonator with dielectric layers disposed bilaterally on the piezoelectric layer;

FIG. 3 is an illustration of a cross-sectional side view of a solidly mounted BAW resonator (BAW SMR) in a first example, including dielectric layers on both sides of a piezoelectric layer and between electrode layers to improve energy efficiency;

FIG. 4 is an illustration of a cross-sectional side view of a film bulk acoustic resonator (FBAR) in a second example, including dielectric layers on both sides of a piezoelectric layer and between electrode layers to improve energy efficiency;

FIG. 5 is a flowchart of a method of making the BAW resonators in FIGS. 3 and 4, including dielectric layers on both sides of a piezoelectric layer and between electrode layers to improve energy efficiency;

FIG. 6 is a block diagram of an exemplary processor-based system that can include a BAW resonator, including dielectric layers on both sides of a piezoelectric layer and between electrode layers to improve energy efficiency; and

FIG. 7 is a block diagram of an exemplary wireless communication device that includes a BAW resonator, including dielectric layers on both sides of a piezoelectric layer and between electrode layers to improve energy efficiency.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include bulk acoustic wave (BAW) resonators, including bilateral dielectric layers for improved quality factor (Q). Methods of making the BAW resonator, including bilateral dielectric layers are also disclosed. As the frequencies of microacoustic filter applications increase to address the needs of future technologies, the quality factor Q, which is a measure of energy efficiency, decreases, and the performance of microacoustic filters based on BAW resonators correspondingly decreases. In an exemplary BAW resonator, dielectric layers are disposed on each side of a piezoelectric layer and between the top and bottom electrode layers, which may be formed of metal, to reduce the acoustic/viscous losses that occur in the electrode layers. Inclusion of the bilateral dielectric layers between the top and bottom electrode layers shifts more energy to non-metallic layers to reduce acoustic energy losses. In some examples, a thickness of each of the dielectric layers may be up to thirty percent of a distance between the top and bottom electrode layers.

To transmit or receive radio-frequency signals within a given frequency band, an electronic device may use filters to pass signals within the frequency band and to suppress (e.g., attenuate) jammers or noise-having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). In an acoustic resonator or an acoustic filter, an electrical signal having a time-varying voltage is applied to an electrode structure (e.g., top and bottom electrode layers) to create an electric field of varying intensity in a piezoelectric material. The piezoelectric material transforms the varying electric field into acoustic waves. The resonant frequencies of acoustic resonators are determined by the dimensions of the acoustic resonator and the electrode structure. The filtered acoustic waves induce an electric field in the piezoelectric material, and the electrode structure detects the electric field as voltage and transforms or converts it to an electrical output signal.

Since higher frequency signals have shorter wavelengths, acoustic resonators having smaller dimensions are needed. Accordingly, it can be challenging to design an acoustic resonator that can provide filtering for signals at higher frequencies, such as those used with Wi-Fi® at 2.4 gigahertz (GHz) frequencies, at 5 GHz frequencies, at frequencies greater than 5 GHz, at sub-6 GHz frequencies, at frequencies between 6 and 18 GHz, and/or at frequencies greater than or equal to 10 GHz. In particular, it can be challenging to design a filter that is affordable and can realize a target level of performance in terms of resonance quality factors, electromechanical coupling, power durability, insertion loss, and spurious-mode suppression.

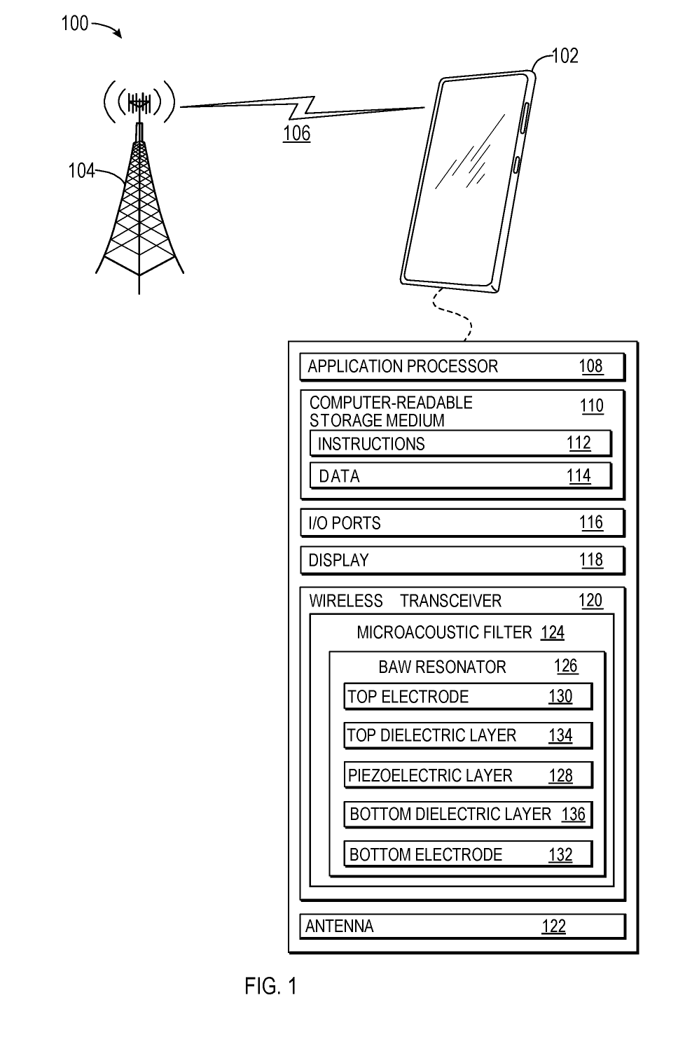

FIG. 1 illustrates an example environment 100 for operating a BAW resonator with bilateral dielectric layers disposed on a piezoelectric layer. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or another internet of things (IoT) device, a medical device, a vehicle-based communication system, a radar, a radio apparatus, and so forth. Use of a microacoustic filter is not limited to wireless communication as a microacoustic filter can be applied in any technological field where such filtering is useful.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), 5th-generation (5G), or 6th-generation (6G) cellular; IEEE 802.11 (e.g., Wi-Fi^{®}); IEEE 802.15 (e.g., Bluetooth^{®}); IEEE 802.16 (e.g., WiMAX^{®}); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102 and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively, or additionally, the display 118 can be implemented as a display port or virtual interface, through which the graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and the networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one microacoustic filter 124, including at least one BAW resonator 126 (e.g., solidly mounted resonator (SMR) or film bulk acoustic resonator (FBAR) in an acoustic filter). In some implementations, the microacoustic filter 124 includes multiple BAW resonators 126, which can be arranged in series, in parallel, in a ladder structure, in a lattice structure, or some combination thereof. The BAW resonator 126 includes a piezoelectric layer 128, a top electrode layer (e.g., metal layer) 130, and a bottom electrode layer 132. The BAW resonator 126 also includes a top dielectric layer 134 and a bottom dielectric layer 136. The designations “top” and “bottom” are indicative of being on opposite sides of the piezoelectric layer 128 but not actually on respective top and bottom sides (in a vertical direction) in some orientations. The top dielectric layer 134 is between the piezoelectric layer 128 and the top electrode layer 130, and the bottom dielectric layer 136 is between the piezoelectric layer 128 and the bottom electrode layer 132. Although no additional layers are shown in FIG. 1, the BAW resonator 126 may include other layers.

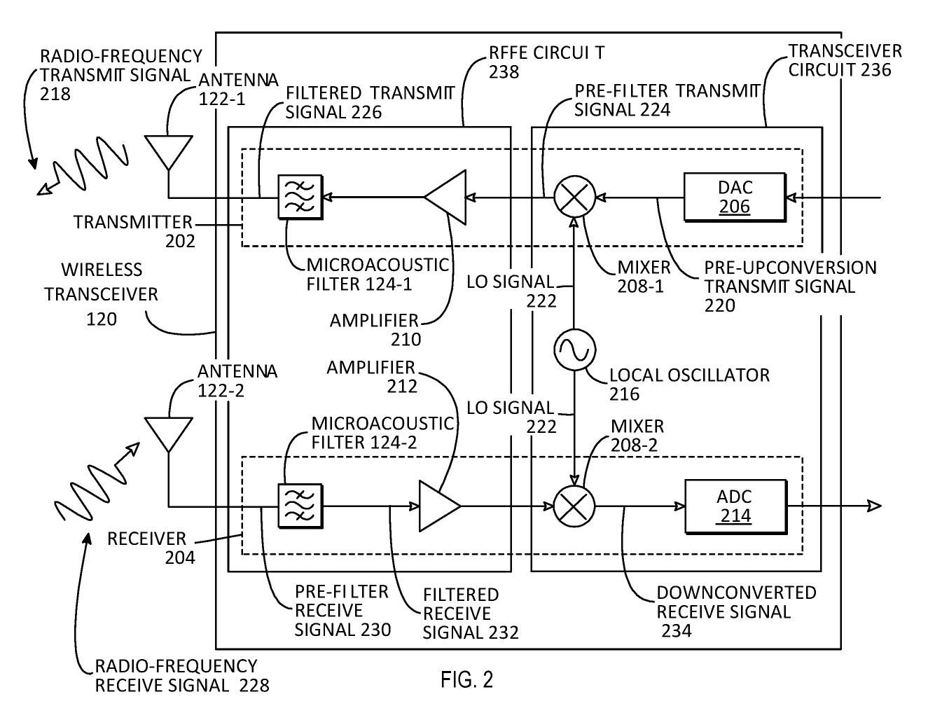

With these improvements, the microacoustic filter 124 can be designed to support frequency ranges above 2 GHz and, in particular, at frequencies above six (6) GHz. The microacoustic filter 124 is further described with respect to FIG. 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one first microacoustic filter 124-1. The receiver 204 includes at least one second microacoustic filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the DAC 206 of the transmitter 202 and the ADC 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the DAC 206 of the transmitter 202, the mixer 208-1 of the transmitter 202, the mixer 208-2 of the receiver 204, and the ADC 214 of the receiver 204. In other implementations, the DAC 206 and the ADC 214 can be implemented on another separate circuit that includes the application processor 108 or the modem. The RFFE circuit 238 includes the amplifier 210 of the transmitter 202, the microacoustic filter 124-1 of the transmitter 202, the microacoustic filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the DAC 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the first microacoustic filter 124-1.

The first microacoustic filter 124-1 filters the amplified pre-filter transmit signal 224 to generate a filtered transmit signal 226. As part of the filtering process, the first microacoustic filter 124-1 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second microacoustic filter 124-2 accepts the received radio-frequency receive signal 228, which is represented by a pre-filter receive signal 230. The second microacoustic filter 124-2 filters any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the LO signal 222 to generate the downconverted receive signal 234. The ADC 214 converts the downconverted receive signal 234 into a digital signal, which can be processed by the application processor 108 or another processor associated with the wireless transceiver 120 (e.g., the modem).

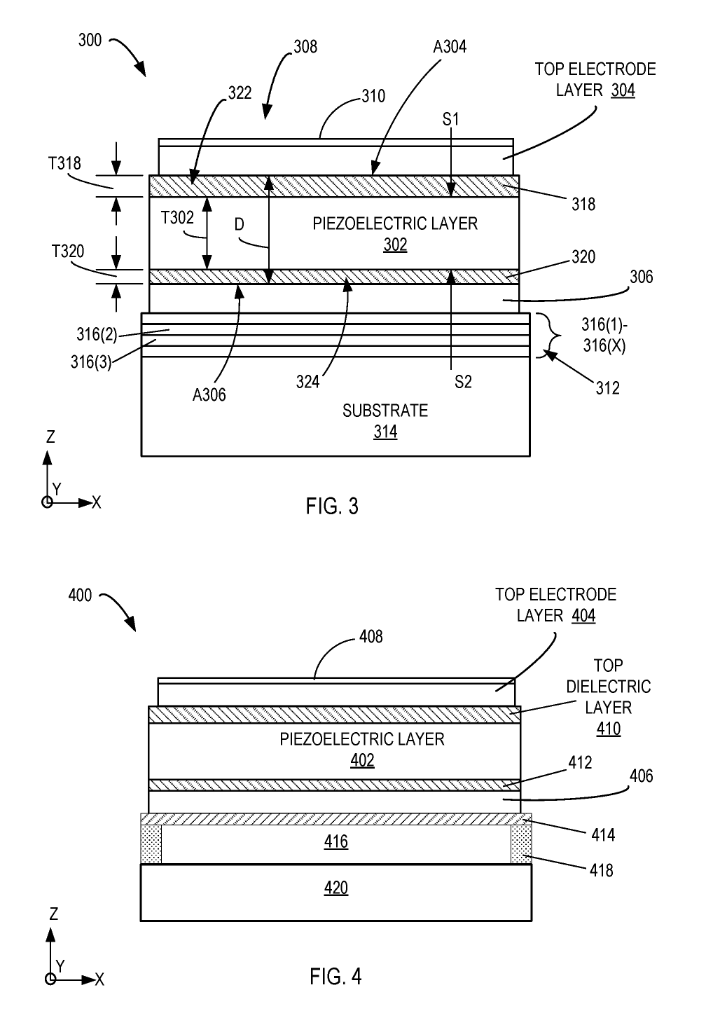

FIG. 2 illustrates one example configuration of the wireless transceiver 120. Other configurations of the wireless transceiver 120 can support multiple frequency bands and share an antenna 122-1 or 122-2 across multiple transceivers. One of ordinary skill in the art can appreciate the variety of other configurations for which microacoustic filters 124 may be included. For example, the microacoustic filters 124 can be integrated within duplexers or diplexers of the wireless transceiver 120. Example implementations of the BAW resonator 126 are further described with respect to FIGS. 3 and 4.

FIG. 3 is an illustration of a cross-sectional side view of one example of a BAW resonator 300, which may be the BAW resonator 126 in FIG. 1, implemented as a BAW SMR. The BAW resonator 300 includes a piezoelectric layer 302, which may be a layer of a compound comprising aluminum (Al) and scandium (Sc), such as AlSc30N, between a first, top electrode layer 304 and a second, bottom electrode layer 306. The top electrode layer 304 and the bottom electrode layer 306 may be layers of a conductive metal, such as molybdenum (Mo), disposed on a first side S1 of the piezoelectric layer 302 and a second side S2 of the piezoelectric layer 302, respectively. A time-varying voltage VIN applied between the top electrode layer 304 and the bottom electrode layer 306 may induce a time-varying electric field in the piezoelectric layer 302 to generate acoustic waves in the piezoelectric layer 302.

Acoustic waves generated in the piezoelectric layer 302 propagate outward in the vertical (e.g., Z-axis) direction upward into the top electrode layer 304, where there is an interface 308 to the environment (e.g., air). Here, the BAW resonator 300 may include a trim layer 310 (e.g., silicon nitride (SiN)), for shifting the resonant frequency and providing electrical insulation and/or protection of the top electrode layer 304 from the environment. The acoustic waves may also propagate vertically downward through the bottom electrode layer 306 and into an acoustic mirror 312. The acoustic mirror 312 is provided to reflect acoustic energy back to the piezoelectric layer 302 to reduce energy losses through a substrate 314 (e.g., Si) on which the acoustic mirror 312 is formed. The acoustic mirror 312 includes layers 316(1)-316(X) that have alternating (higher and lower) levels of acoustic impedance to reflect the acoustic energy. For example, the layers 316(1)-316(X) may include layers of silicon dioxide (SiO₂) in layers 316(1) and 316(3) and layers of tungsten (W) in layers 316(2) and 316(X) (where X=4 in this example but is not limited thereto).

The acoustic waves generated in the piezoelectric layer 302 propagate (e.g., resonate) at frequencies (e.g., within a certain bandwidth) that are based on the acoustic properties of the BAW resonator 300 to provide desired frequency filtration. Acoustic energy losses in the BAW resonator 300 reduce the intensity of the output signal. which, thereby, reduces the overall efficiency, which may be measured as the Q factor.

One source of energy loss that increases with an operating frequency of the BAW resonator is acoustic/viscous loss within the metal layers of the top and bottom electrode layers 304 and 306. For this reason, in an exemplary aspect, a first, top dielectric layer 318 is included between the first side S1 of the piezoelectric layer 302 and the top electrode layer 304, and a second, bottom dielectric layer 320 is included between the second side S2 of the piezoelectric layer 302 and the bottom electrode layer 306. In some examples, the top dielectric layer 318 is in direct contact with the first side S1 of the piezoelectric layer 302, and the bottom dielectric layer 320 is in direct contact with the second side S2 of the piezoelectric layer 302. Thus, in some examples, the top dielectric layer 318 is in direct contact with the top electrode layer 304, and the bottom dielectric layer 320 is in direct contact with the bottom electrode layer 306.

Rather than positioning the top and bottom electrode layers 304 and 306 directly in contact with the piezoelectric layer 302 in which the acoustic energy is generated and sensed, the top and bottom dielectric layers 318 and 320 provide separation of the top and bottom electrode layers 304 and 306 from the piezoelectric layer 302 to reduce acoustic energy losses. Adding the top and bottom dielectric layers 318 and 320 to the acoustically active region shifts more acoustic energy into the dielectric layers 318 and 320 and away from the top and bottom electrode layers 304 and 306 to reduce acoustic losses. In this regard, the energy efficiency of the BAW resonator 300 may be improved.

In the example shown in FIG. 3, there is a distance D in the Z-axis direction between the top electrode layer 304 and the bottom electrode layer 306. The Z-axis direction is orthogonal to the top electrode layer 304 and orthogonal to the bottom electrode layer 306. The piezoelectric layer 302, as shown in FIG. 3, has a thickness T302 in the first (Z-axis) direction. In some examples, the thickness T302 of the piezoelectric layer 302 in the Z-axis direction is in a range of forty percent (40%) to ninety percent (90%) of the distance D from the top electrode layer 304 to the bottom electrode layer 306.

The top dielectric layer 318 has a thickness T318 in the Z-axis direction in FIG. 3, and the bottom dielectric layer 320 has a thickness T320 in the Z-axis direction. The thickness T318 may be the same as or different from the thickness T320. In some examples, a total of the thickness T318 of the top dielectric layer 318 and the thickness T320 of the bottom dielectric layer 320 is in a range of ten percent (10%) to sixty percent (60%) of the distance D. The thicknesses T318 and T320 may be customized for optimal results.

The top dielectric layer 318 may be a first material 322 including one or more of silicon dioxide (SiO₂), silicon nitride (SiN), and silicon oxyfluoride (SiOF). The bottom dielectric layer 320 may be a second material 324, including one or more of silicon dioxide (SiO₂), silicon nitride (SiN), and silicon oxyfluoride (SiOF). The first material 322 of the top dielectric layer 318 may be different from the second material 324 of the bottom dielectric layer 320.

The top electrode layer 304 extends in an area A304 in a plane extending in the X-axis and Y-axis directions, orthogonal to the Z-axis direction. The second electrode layer 306 extends in an area A306 that may be parallel to the top electrode layer 304. In some examples, the first material 322 of the top dielectric layer 318 is disposed on the entire area A304 of the top electrode layer 304 between the top electrode layer 304 and the piezoelectric layer 302, and the second material 324 of the bottom dielectric layer 320 is disposed on the entire area A306 of the bottom electrode layer 306 between the bottom electrode layer 306 and the piezoelectric layer 302.

FIG. 4 is an illustration of a cross-sectional side view of a second example of a BAW resonator 400, which may be the BAW resonator 126 in FIG. 1, implemented as an FBAR. The BAW resonator 400 includes a piezoelectric layer 402, a first, top electrode layer 404, and a second, bottom electrode layer 406. A trim layer 408 may be included on the top electrode layer 404 for protection from the environment. To improve energy efficiency, as discussed above, the BAW resonator 400 includes a first, top dielectric layer 410 between the piezoelectric layer 402 and the top electrode layer 404, and a second, bottom dielectric layer 412 between the piezoelectric layer 402 and the bottom electrode layer 406. The acoustic energy in the active region of the BAW resonator 400 is shifted from the top and bottom electrode layers 404 and 406 into the top dielectric layer 410 and the bottom dielectric layer 412 to reduce energy losses. In this regard, the top and bottom dielectric layers 410 and 412 provide a similar benefit in the BAW resonator 400 as the BAW resonator 300, even though the bottom electrode layer 406 is disposed on a thin film 414 rather than an acoustic mirror. Here, acoustic energy reflects back to the piezoelectric layer 402 when it reaches an air cavity 416 below the thin film 414. The BAW resonator 400 includes a frame 418 between the bottom electrode layer 406 and a supporting substrate 420. The frame 418 supports the BAW resonator 400 on the substrate 420 such that air cavity 416 is formed between the bottom electrode layer 406 and the substrate 420.

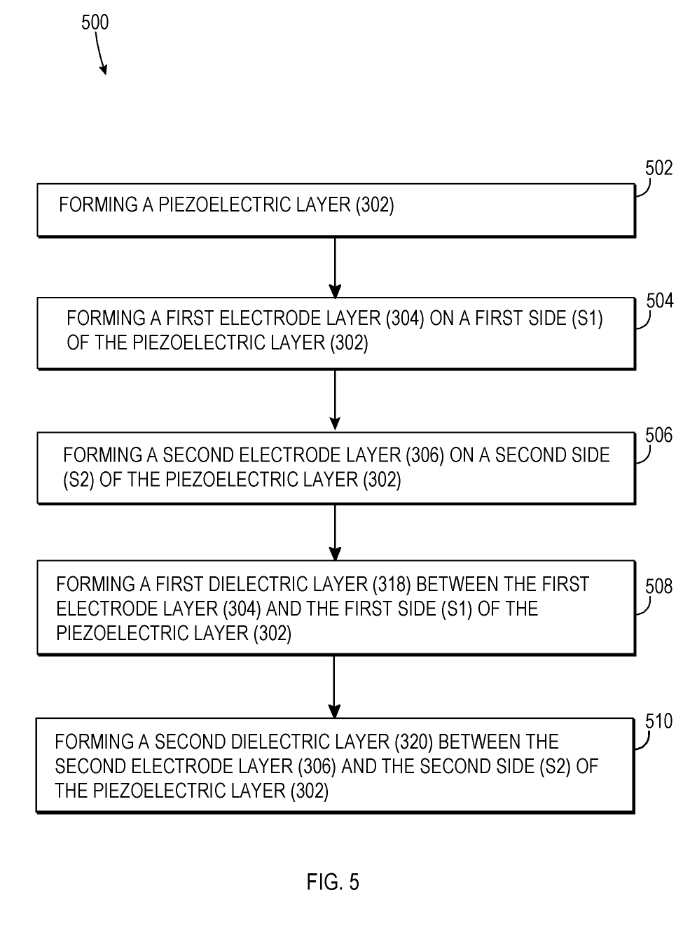

FIG. 5 is a flowchart of a method 500 of making the BAW resonator 400 in FIGS. 3 and 4. The method 500 includes forming a piezoelectric layer 302 (block 502), forming a first electrode layer 304 on a first side S1 of the piezoelectric layer 302 (block 504), and forming a second electrode layer 306 on a second side S2 of the piezoelectric layer 302 (block 506). The method 500 includes forming a first dielectric layer 318 between the first electrode layer 304 and the first side S1 of the piezoelectric layer 302 (block 508) and forming a second dielectric layer 320 between the second electrode layer 306 and the second side S2 of the piezoelectric layer 302 (block 510).

The method 500 may include disposing the second electrode layer 306 on either an acoustic mirror 312 in an SMR, as shown in FIG. 3, or a thin film 414 in an FBAR, as shown in FIG. 4. When forming the BAW resonator 300 as shown in FIG. 3, the method 500 may further include forming the piezoelectric layer 302 on a sacrificial layer (not shown) and forming the first dielectric layer 318 directly on the first side S1 of the piezoelectric layer 302. The method further includes removing the sacrificial layer from the piezoelectric layer 302 and forming the second dielectric layer 320 on the second side S2 of the piezoelectric layer 302. Additionally, the method 500 may further include forming the second electrode layer 306 on an acoustic mirror 312.

Alternatively, when forming the BAW resonator 400 as shown in FIG. 4, the method 500 may include forming the piezoelectric layer 402 on a sacrificial layer (not shown), forming the first dielectric layer 410 directly on the first side S1 of the piezoelectric layer 402, removing the sacrificial layer from the second side S2 of the piezoelectric layer 402 and forming a thin film 414. The method further includes forming the second electrode layer 406, forming the second dielectric layer 412 on the second electrode 406, and positioning the second dielectric layer 412 in direct contact with the second side S2 of the piezoelectric layer 402. The method further includes forming a frame 418 on a substrate 420 (e.g., Si), and disposing the thin film 414 on the frame 418, wherein an air cavity 416 is formed between the thin film 414 and the substrate 420.

BAW resonators 300 and 400, having dielectric layers bilaterally disposed on the piezoelectric layer between the top and bottom electrode layers to improve energy efficiency, may be integrated into any processor-based device. Examples of such processor-based devices, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

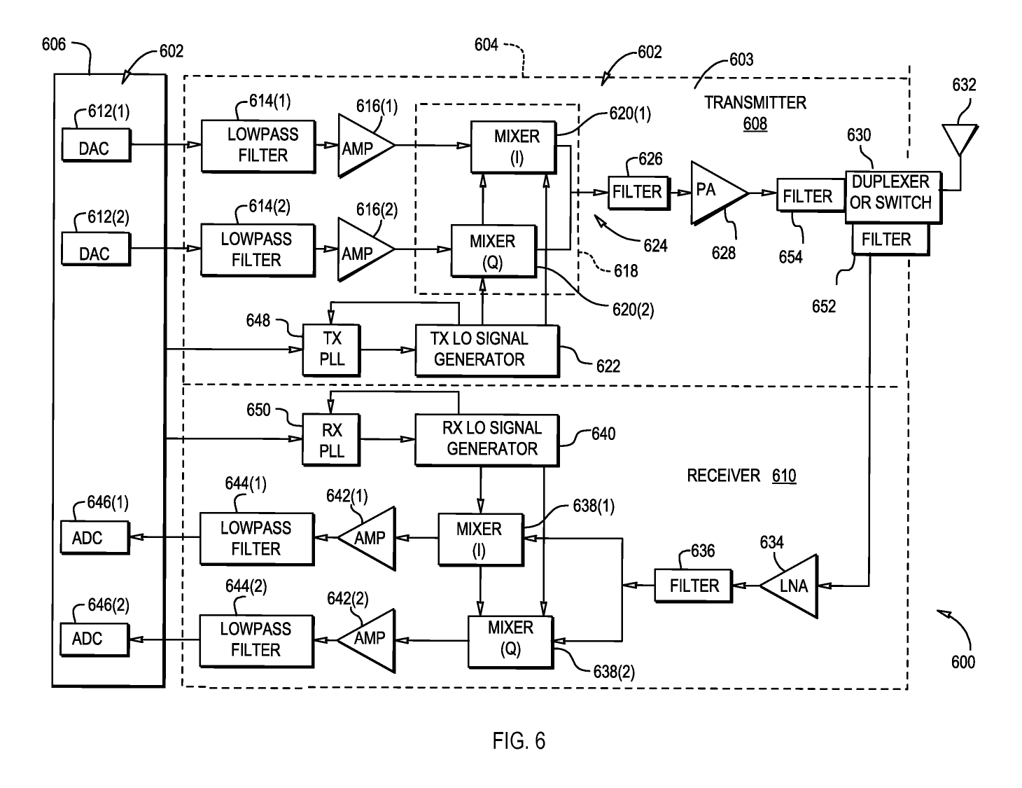

FIG. 6 illustrates an exemplary wireless communications device 600 that includes radio-frequency (RF) components formed from one or more ICs 602, wherein any of the ICs 602 may include dielectric layers bilaterally disposed on a piezoelectric layer between top and bottom electrode layers to improve energy efficiency which may be integrated into any processor-based device, as shown in FIGS. 3 and 4. The wireless communications device 600 may include or be provided in any of the above-referenced devices, as examples. As shown in FIG. 6, the wireless communications device 600 includes a transceiver 604 and a data processor 606. The data processor 606 may include a memory to store data and program codes. The transceiver 604 includes a transmitter 608 and a receiver 610 that support bi-directional communications. In general, the wireless communications device 600 may include any number of transmitters 608 and/or receivers 610 for any number of communication systems and frequency bands. All or a portion of the transceiver 604 may be implemented on one or more analog ICs, RF ICs (RFICs), mixed-signal ICs, etc.

The transmitter 608 or the receiver 610 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage and then from IF to baseband in another stage for the receiver 610. In the direct-conversion architecture, a signal is frequency-converted between RF and baseband in one stage. The super-heterodyne and direct-conversion architectures may use different circuit blocks and/or have different requirements. In the wireless communications device 600 in FIG. 6, the transmitter 608 and the receiver 610 are implemented with the direct-conversion architecture.

In the transmit path, the data processor 606 processes data to be transmitted and provides I and Q analog output signals to the transmitter 608. In the exemplary wireless communications device 600, the data processor 606 includes digital-to-analog converters (DACs) 612(1), 612(2) for converting digital signals generated by the data processor 606 into the I and Q analog output signals (e.g., I and Q output currents) for further processing.

Within the transmitter 608, lowpass filters 614(1), 614(2) filter the I and Q analog output signals, respectively, to remove undesired signals caused by the prior digital-to-analog conversion. Amplifiers (AMPs) 616(1), 616(2) amplify the signals from the lowpass filters 614(1), 614(2), respectively, and provide I and Q baseband signals. An upconverter 618 upconverts the I and Q baseband signals with I and Q transmit (TX) local oscillator (LO) signals through mixers 620(1), 620(2) from a TX LO signal generator 622 to provide an upconverted signal 624. A filter 626 filters the upconverted signal 624 to remove undesired signals caused by the frequency up-conversion as well as noise in a receive frequency band. A power amplifier (PA) 628 amplifies the upconverted signal 624 from the filter 626 to obtain the desired output power level and provides a transmit RF signal. The transmit RF signal is routed through a duplexer or switch 630 and transmitted via an antenna 632.

In the receive path, the antenna 632 receives signals transmitted by base stations and provides a received RF signal, which is routed through the duplexer or switch 630 and provided to a low noise amplifier (LNA) 634. The duplexer or switch 630 is designed to operate with a specific receive (RX)-to-TX duplexer frequency separation, such that RX signals are isolated from TX signals. The received RF signal is amplified by the LNA 634 and filtered by a filter 636 to obtain a desired RF input signal. Down-conversion mixers 638(1), 638(2) mix the output of the filter 636 with I and Q RX LO signals (i.e., LO_I and LO_Q) from an RX LO signal generator 640 to generate I and Q baseband signals. The I and Q baseband signals are amplified by AMPs 642(1), 642(2) and further filtered by lowpass filters 644(1), 644(2) to obtain I and Q analog input signals, which are provided to the data processor 606. In this example, the data processor 606 includes analog-to-digital converters (ADCs) 646(1), 646(2) for converting the analog input signals into digital signals to be further processed by the data processor 606.

In the wireless communications device 600 of FIG. 6, the TX LO signal generator 622 generates the I and Q TX LO signals used for frequency up-conversion, while the RX LO signal generator 640 generates the I and Q RX LO signals used for frequency down-conversion. Each LO signal is a periodic signal with a particular fundamental frequency. A TX phase-locked loop (PLL) circuit 648 receives timing information from the data processor 606 and generates a control signal used to adjust the frequency and/or phase of the TX LO signals from the TX LO signal generator 622. Similarly, an RX PLL circuit 650 receives timing information from the data processor 606 and generates a control signal used to adjust the frequency and/or phase of the RX LO signals from the RX LO signal generator 640.

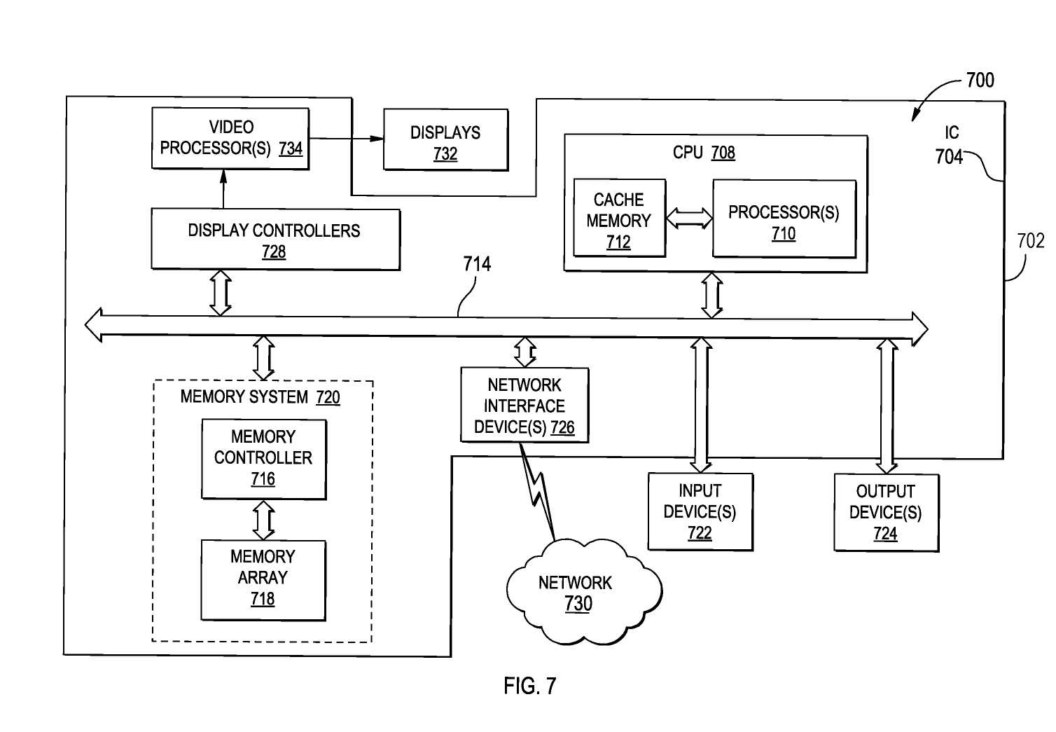

In this regard, FIG. 7 illustrates an example of a processor-based system 700 that can include dielectric layers bilaterally disposed on a piezoelectric layer between top and bottom electrode layers to improve energy efficiency which may be integrated into any processor-based device, as shown in FIGS. 3 and 4. The processor-based system 700 includes a central processing unit (CPU) 708 that includes one or more processors 710, which may also be referred to as CPU cores or processor cores. The CPU 708 may have cache memory 712 coupled to the CPU 708 for rapid access to temporarily stored data. The CPU 708 is coupled to a system bus 714 and can intercouple master and slave devices included in the processor-based system 700. As is well known, the CPU 708 communicates with these other devices by exchanging address, control, and data information over the system bus 714. For example, the CPU 708 can communicate bus transaction requests to a memory controller 716, as an example of a slave device. Although not illustrated in FIG. 7, multiple system buses 714 could be provided, wherein each system bus 714 constitutes a different fabric.

Other master and slave devices can be connected to the system bus 714. As illustrated in FIG. 7, these devices can include a memory system 720 that includes the memory controller 716 and a memory array(s) 718, one or more input devices 722, one or more output devices 724, one or more network interface devices 726, and one or more display controllers 728, as examples. The input device(s) 722 can include any type of input device, including, but not limited to, input keys, switches, voice processors, etc. The output device(s) 724 can include any type of output device, including, but not limited to, audio, video, other visual indicators, etc. The network interface device(s) 726 can be any device configured to allow an exchange of data to and from a network 730. The network 730 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 726 can be configured to support any type of communications protocol desired.

The CPU 708 may also be configured to access the display controller(s) 728 over the system bus 714 to control information sent to one or more displays 732. The display controller(s) 728 sends information to the display(s) 732 to be displayed via one or more video processor(s) 734, which processes the information to be displayed into a format suitable for the display(s) 732. The display(s) 732 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:

1. A bulk acoustic wave (BAW) resonator comprising:

a piezoelectric layer;

a first electrode layer on a first side of the piezoelectric layer;

a second electrode layer on a second side of the piezoelectric layer;

a first dielectric layer between the first electrode layer and the first side of the piezoelectric layer; and

a second dielectric layer between the second electrode layer and the second side of the piezoelectric layer.

2. The BAW resonator of clause 1, wherein:

a first thickness of the piezoelectric layer in a first direction orthogonal to the first electrode layer and the second electrode layer is in a range of forty (40) percent (%) to ninety (90)% of a distance in the first direction from the first electrode layer to the second electrode layer.

3. The BAW resonator of clause 1 or clause 2, wherein:

a total of a second thickness of the first dielectric layer in the first direction and a third thickness of the second dielectric layer in the first direction is in a range of ten (10)% to sixty (60)% of the distance in the first direction from the first electrode layer to the second electrode layer.

4. The BAW resonator of clause 3, wherein the second thickness is different from the third thickness.

5. The BAW resonator of any of clause 1 to clause 4, wherein:

the first dielectric layer is in direct contact with the first side of the piezoelectric layer; and

the second dielectric layer is in direct contact with the second side of the piezoelectric layer.

6. The BAW resonator of any of clause 1 to clause 5, wherein:

the first dielectric layer is in direct contact with the first electrode layer; and

the second dielectric layer is in direct contact with the second electrode layer.

7. The BAW resonator of any of clause 1 to clause 6, wherein:

the first dielectric layer comprises a first material comprising one of silicon dioxide (SiO₂), silicon nitride (SiN), and silicon oxyfluoride (SiOF); and

the second dielectric layer comprises a second material comprising one of silicon dioxide (SiO₂), silicon nitride (SiN), and silicon oxyfluoride (SiOF).

8. The BAW resonator of clause 7, wherein the first material is different from the second material.

9. The BAW resonator of clause 7 or clause 8, wherein:

the first material is disposed on an entire area of the first electrode layer; and

the second material is disposed between the second electrode layer and the piezoelectric layer in an entire area of the second electrode layer.

10. The BAW resonator of any of clause 1 to clause 9, further comprising:

a substrate; and

an acoustic mirror between the second electrode layer and the substrate.

11. The BAW resonator of any of clause 1 to clause 9, further comprising:

a substrate;

a frame structure between the second electrode layer and the substrate; and

an air cavity between the second electrode layer and the substrate.

12. The BAW resonator of any of clause 1 to clause 11 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

13. A method of manufacturing a bulk acoustic wave (BAW) resonator, the method comprising:

forming a piezoelectric layer;

forming a first electrode layer on a first side of the piezoelectric layer;

forming a second electrode layer on a second side of the piezoelectric layer;

forming a first dielectric layer between the first electrode layer and the first side of the piezoelectric layer; and

forming a second dielectric layer between the second electrode layer and the second side of the piezoelectric layer.

14. The method of clause 13, further comprising:

forming the piezoelectric layer on a sacrificial layer;

forming the first dielectric layer directly on the first side of the piezoelectric layer;

removing the sacrificial layer from the piezoelectric layer;

forming the second dielectric layer on the second side of the piezoelectric layer.

15. The method of clause 13 or clause 14, further comprising forming the second electrode layer on an acoustic mirror.

16. The method of clause 13, further comprising:

forming the piezoelectric layer on a sacrificial layer;

forming the first dielectric layer directly on the first side of the piezoelectric layer;

removing the sacrificial layer from the second side of the piezoelectric layer;

forming a thin film;

forming the second electrode layer on the thin film;

forming the second dielectric layer on the second electrode layer; and

positioning the second dielectric layer in direct contact with the second side of the piezoelectric layer.

17. The method of clause 16, further comprising:

forming a frame on a substrate; and

disposing the thin film on the frame,

wherein an air cavity is formed between the thin film and the substrate.

18. The method of any of clause 13 to clause 17, wherein a first thickness of the piezoelectric layer in a first direction orthogonal to the first electrode layer and the second electrode layer is in a range of forty (40) percent (%) to ninety (90)% of a distance in the first direction from the first electrode layer to the second electrode layer.

19. The method of any of clause 13 to clause 18, wherein a second thickness of the first dielectric layer is different from a third thickness of the second dielectric layer.

20. The method of clause 13, further comprising:

forming the first dielectric layer of a first material comprising one of silicon dioxide (SiO₂), silicon nitride (SiN), and silicon oxyfluoride (SiOF); and

forming the second dielectric layer of a second material comprising one of silicon dioxide (SiO₂), silicon nitride (SiN), and silicon oxyfluoride (SiOF).

What is claimed is:

1. A bulk acoustic wave (BAW) resonator comprising:
a piezoelectric layer;
a first electrode layer on a first side of the piezoelectric layer;
a second electrode layer on a second side of the piezoelectric layer;
a first dielectric layer between the first electrode layer and the first side of the piezoelectric layer; and
a second dielectric layer between the second electrode layer and the second side of the piezoelectric layer.

2. The BAW resonator of claim 1, wherein:
a first thickness of the piezoelectric layer in a first direction orthogonal to the first electrode layer and the second electrode layer is in a range of forty (40) percent (%) to ninety (90)% of a distance in the first direction from the first electrode layer to the second electrode layer.

3. The BAW resonator of claim 2, wherein:
a total of a second thickness of the first dielectric layer in the first direction and a third thickness of the second dielectric layer in the first direction is in a range of ten (10)% to sixty (60)% of the distance in the first direction from the first electrode layer to the second electrode layer.

4. The BAW resonator of claim 3, wherein the second thickness is different from the third thickness.

5. The BAW resonator of claim 1, wherein:
the first dielectric layer is in direct contact with the first side of the piezoelectric layer; and
the second dielectric layer is in direct contact with the second side of the piezoelectric layer.

6. The BAW resonator of claim 5, wherein:
the first dielectric layer is in direct contact with the first electrode layer; and
the second dielectric layer is in direct contact with the second electrode layer.

7. The BAW resonator of claim 1, wherein:
the first dielectric layer comprises a first material comprising one of silicon dioxide (SiO₂), silicon nitride (SiN), and silicon oxyfluoride (SiOF); and
the second dielectric layer comprises a second material comprising one of silicon dioxide (SiO₂), silicon nitride (SiN), and silicon oxyfluoride (SiOF).

8. The BAW resonator of claim 7, wherein the first material is different from the second material.

9. The BAW resonator of claim 7, wherein:
the first material is disposed on an entire area of the first electrode layer; and
the second material is disposed between the second electrode layer and the piezoelectric layer in an entire area of the second electrode layer.

10. The BAW resonator of claim 1, further comprising:
a substrate; and
an acoustic mirror between the second electrode layer and the substrate.

11. The BAW resonator of claim 1, further comprising:
a substrate;
a frame structure between the second electrode layer and the substrate; and
an air cavity between the second electrode layer and the substrate.

12. The BAW resonator of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

13. A method of manufacturing a bulk acoustic wave (BAW) resonator, the method comprising:
forming a piezoelectric layer;
forming a first electrode layer on a first side of the piezoelectric layer;
forming a second electrode layer on a second side of the piezoelectric layer;
forming a first dielectric layer between the first electrode layer and the first side of the piezoelectric layer; and
forming a second dielectric layer between the second electrode layer and the second side of the piezoelectric layer.

14. The method of claim 13, further comprising:
forming the piezoelectric layer on a sacrificial layer;
forming the first dielectric layer directly on the first side of the piezoelectric layer;
removing the sacrificial layer from the piezoelectric layer;
forming the second dielectric layer on the second side of the piezoelectric layer.

15. The method of claim 14, further comprising forming the second electrode layer on an acoustic mirror.

16. The method of claim 13, further comprising:
forming the piezoelectric layer on a sacrificial layer;
forming the first dielectric layer directly on the first side of the piezoelectric layer;
removing the sacrificial layer from the second side of the piezoelectric layer;
forming a thin film;
forming the second electrode layer on the thin film;
forming the second dielectric layer on the second electrode layer; and
positioning the second dielectric layer in direct contact with the second side of the piezoelectric layer.

17. The method of claim 16, further comprising:
forming a frame on a substrate; and
disposing the thin film on the frame,
wherein an air cavity is formed between the thin film and the substrate.

18. The method of claim 13, wherein a first thickness of the piezoelectric layer in a first direction orthogonal to the first electrode layer and the second electrode layer is in a range of forty (40) percent (%) to ninety (90)% of a distance in the first direction from the first electrode layer to the second electrode layer.

19. The method of claim 13, wherein a second thickness of the first dielectric layer is different from a third thickness of the second dielectric layer.

20. The method of claim 13, further comprising:
forming the first dielectric layer of a first material comprising one of silicon dioxide (SiO₂), silicon nitride (SiN), and silicon oxyfluoride (SiOF); and
forming the second dielectric layer of a second material comprising one of silicon dioxide (SiO₂), silicon nitride (SiN), and silicon oxyfluoride (SiOF).
